(19) United States
(12) Patent Application Publication
(10) Pub. No.: US 2007/0042539 A1
(43) Pub. Date: Feb. 22, 2007

(54) Method of manufacturing a non-volatile memory device

(75) Inventors: Young-Cheon Jeong, Yongin-si (KR); Chul-Soon Kwon, Seoul (KR); Jae-Min Yu, Anyang-si (KR); Jae-Hyun Park, Yongin-si (KR); Ji-Woon Rim, Seoul (KR); In-Gu Yoon, Uiwang-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/504,422

(22) Filed: Aug. 15, 2006

(30) Foreign Application Priority Data
Aug. 17, 2005 (KR) 10-2005-0075126

(51) Int. Cl. H01L 21/8238

(52) U.S. Cl. 438/201

(57) ABSTRACT

In a method of manufacturing a non-volatile memory device, a first gate insulation layer and a conductive layer are formed on a substrate and then the conductive layer is partially oxidized to form an oxide layer pattern. The conductive layer is partially etched using the oxide layer pattern as an etching mask to form a floating gate electrode on the first gate insulation layer and then the silicon layer is formed on the substrate including the floating gate electrode. The silicon layer is oxidized to form a tunnel insulation layer and a second gate insulation layer on a sidewall of the floating gate electrode and on a surface portion of the substrate adjacent to the floating gate electrode and then a control gate electrode is formed on the tunnel insulation layer and the second gate insulation layer.

### CROSS-REFERENCE TO RELATED APPLICATIONS

This application claims priority under 35 USC § 119 to Korean Patent Application No. 10-2005-0075126 filed on Aug. 17, 2005, the contents of which are herein incorporated by reference in their entirety.

### BACKGROUND OF THE INVENTION

1. Field of the Invention

Example embodiments of the present invention relate to methods of manufacturing non-volatile memory devices, and more particularly, to methods of manufacturing split gate type non-volatile memory devices.

2. Description of the Related Art

Semiconductor memory devices can be generally categorized as volatile memory devices such as dynamic random access memory (DRAM) devices or static random access memory (SRAM) devices, and non-volatile memory devices such as erasable programmable read only memory (EPROM) devices, electrically erasable programmable read only memory (EEPROM) devices or flash memory devices.

Volatile memory devices have a relatively high operating speed for inputting and outputting data and do not retain information when power is removed, whereas non-volatile memory devices have a relatively low operating speed and maintain information when power is removed. Non-volatile memory devices have been in great demand, especially for incorporation into portable devices. In non-volatile flash memory devices, data is electrically stored (i.e., programmed) or erased through a Fowler-Nordheim (F-N) tunneling mechanism or a channel hot electron injection mechanism.

A conventional stacked gate type flash memory device includes a tunnel insulating layer formed on a semiconductor substrate such as a silicon wafer, a floating gate electrode, a dielectric layer and a control gate electrode. A conventional split gate type flash memory device includes a gate insulation layer formed on a semiconductor substrate, a floating gate formed on the gate insulation layer, an oxide layer pattern formed on the floating gate electrode, a tunnel insulating layer formed on a sidewall of the floating gate electrode and a control gate electrode formed on the tunnel insulating layer. Examples of the split gate type flash memory devices are disclosed in U.S. Pat. No. 5,029,130, U.S. Pat. No. 5,045,488, and U.S. Pat. No. 5,067,108.

A method of manufacturing the conventional split gate type flash memory device is described as follows.

FIGS. 1 to 5 are cross-sectional views illustrating a method of manufacturing the conventional split gate type flash memory device.

Referring to FIG. 1, a gate insulation layer 12, or a coupling insulation layer, is formed on a semiconductor substrate 10 such as a silicon wafer. The gate insulation layer 12 may be formed using silicon oxide. The gate insulation layer 12 may be formed by a thermal oxidation process.

A first conductive layer 14, which is to be patterned to form a floating gate electrode in a subsequent process, is formed on the gate insulation layer 12. The first conductive layer 14 may be formed using doped polysilicon. The first conductive layer 14 may be formed by a chemical vapor deposition (CVD) process and an impurity doping process.

A mask pattern 16 is formed on the first conductive layer 14. The mask pattern 16 includes an opening 16a through which a portion of the first conductive layer 14 is exposed. The exposed portion of the first conductive layer 14 is oxidized to form an oxidation layer pattern 18. Edge portions of the oxidation layer pattern 18 have extension features that are commonly referred to as “bird's beaks” features.

Referring to FIG. 2, the mask pattern 16 is removed from the first conductive layer 14, and the first conductive layer 14 is partially etched off using the oxide layer pattern 18 as an etching mask to form the floating gate electrode 20 on the gate insulation layer 12. The floating gate electrode 20 can include tip portions 20a that have shapes corresponding to the beak shapes of the edge portions of the oxide layer pattern 18.

Referring to FIG. 3, lateral portions of the floating gate electrode 20 are oxidized to form tunnel oxide layers 22 on a first sidewall and a second sidewall of the floating gate electrode 20. The tunnel oxide layers 22 may be formed by a thermal oxidation process. In the thermal oxidation process, silicon atoms on a surface of the floating gate electrode 20 may be consumed. Thus, a width of the floating gate electrode 20 may decrease and an edge profile of the floating gate electrode 20 may vary. A decrease of the width of the floating gate electrode 20 may cause the flash memory device to have deteriorated operation characteristics. Further, variation of the tip profile may deteriorate data erasing characteristics of the flash memory device and may decrease productivity of the flash memory device.

Referring to FIG. 4, a second conductive layer (not shown) is formed on an entire surface of the semiconductor substrate 10 including the tunnel oxide layers 22. The second conductive layer is patterned to form a control gate electrode 24. The control gate electrode 24 is positioned on a portion of the tunnel oxide layers 22 formed on the first sidewall of the floating gate electrode 20, on a portion of the gate insulation layer 12 formed on the semiconductor substrate 10 adjacent to the first sidewall and on a portion of the oxide layer pattern 18.

Referring to FIG. 5, impurities are implanted by an ion implantation process using the control gate electrode 24, the oxide layer pattern 18 and the floating gate electrode 20 as masks to form a source region 26 and a drain region 28 at portions of the semiconductor substrate 10 adjacent to the floating gate electrode 20 and the control gate electrode 24, respectively. The impurities are diffused into a channel region positioned below the floating gate electrode 20. Therefore, the source region 26 includes a low concentration impurity region 26a.

In an etching process for forming the control gate electrode 24, a portion of the tunnel oxide layers 22 formed on a second sidewall of the floating gate electrode 20 and the gate insulation layer 12 formed on the semiconductor substrate 10 can become damaged. In order to cure such damage, a re-oxidation process is performed. The re-oxidation process may include a thermal oxidation process, which may cause a thickness of the gate insulation layer 12 adjacent to the second sidewall of the floating gate electrode 20 to become thicker. Such a thickness variation of the gate insulation layer 12, may, in turn, further deteriorate programming characteristics of the flash memory device.

### SUMMARY OF THE INVENTION

The present invention provides methods of manufacturing non-volatile memory devices each having an improved tip profile of a floating gate electrode and a uniform thickness of a gate insulation layer.

In one aspect, the present invention is directed to a method of manufacturing a non-volatile memory device, comprising: forming a first gate insulation layer and a conductive layer on a substrate; forming an oxide layer pattern by partially oxidizing a top portion of the conductive layer; forming a floating gate electrode on the first gate insulation layer by patterning the conductive layer using the oxide layer pattern as an etching mask; forming a silicon layer on the substrate including the floating gate electrode; forming a tunnel insulation layer on a sidewall of the floating gate electrode and a second gate insulation layer on the first gate insulation layer by oxidizing the silicon layer; and forming a control gate electrode on the tunnel insulation layer and the second gate insulation layer.

In one embodiment, forming the oxide layer pattern comprises: forming a mask pattern on the conductive layer, the mask pattern including an opening through which a portion of the conductive layer is exposed; and oxidizing the exposed portion of the conductive layer pattern to form the oxide layer pattern.

In another embodiment, the conductive layer includes polysilicon doped with impurities.

In another embodiment, the silicon layer includes one selected from the group consisting of a single crystalline silicon layer, a poly crystalline silicon layer, and an amorphous silicon layer.

In another embodiment, a thickness ratio between the tunnel insulation layer and the silicon layer is in a range of about 1.0:0.4 to about 1.0:0.5.

In another embodiment, the tunnel insulation layer is formed by a thermal oxidation process.

In another embodiment, forming the control gate electrode comprises: forming a second conductive layer on the substrate including the tunnel insulation layer and the second gate insulation layer; and patterning the second conductive layer to form the control gate electrode, the control gate electrode being positioned both on the tunnel insulation layer formed on the sidewall of the floating gate electrode and on a portion of the second gate insulation layer adjacent to the floating gate electrode.

In another embodiment, the method further comprises: forming a low concentration impurity diffusion region at a surface portion of the substrate adjacent to the floating gate electrode; and forming high concentration impurity diffusion regions at surface portions of the substrate adjacent to the floating gate electrode and the control gate electrode respectively.

In another aspect, the present invention is directed to a method of manufacturing a non-volatile memory device, comprising: forming a gate insulation layer and a conductive layer on a substrate; forming an oxide layer pattern by partially oxidizing a top portion of the conductive layer; forming a floating gate electrode on the first gate insulation layer by patterning the conductive layer using the oxide layer pattern as an etching mask; forming a tunnel insulation layer by oxidizing a surface of the floating gate electrode; forming a control gate electrode on the tunnel insulation layer formed on a sidewall of the floating gate electrode, and on a portion of the gate insulation layer formed on the substrate adjacent to the floating gate electrode; forming a silicon layer on the substrate including the control gate electrode; and oxidizing the silicon layer by thermal oxidation.

In one embodiment, the control gate electrode includes a polysilicon doped with impurities.

In another aspect, the present invention is directed to a method of manufacturing a non-volatile memory device, comprising: forming a gate insulation layer and a conductive layer on a substrate; forming an oxide layer pattern by partially oxidizing a top portion of the conductive layer; forming a floating gate electrode on the first gate insulation layer by patterning the conductive layer using the oxide layer pattern as an etching mask; forming a tunnel insulation layer by oxidizing a surface of the floating gate electrode; forming a control gate electrode on the tunnel insulation layer formed on a sidewall of the floating gate electrode, and on a portion of the gate insulation layer formed on the substrate adjacent to the floating gate electrode; and forming a high temperature oxidation layer on the substrate including the control gate electrode.

In one embodiment, the high temperature oxidation layer is formed by a chemical vapor deposition process at a temperature of about 700° C. to about 900° C.

In another aspect, the present invention is directed to a method of manufacturing a non-volatile memory device, comprising: forming a first gate insulation layer and a conductive layer on a substrate; forming an oxide layer pattern by partial oxidizing a top portion of the conductive layer; forming a floating gate electrode on the first gate insulation layer by patterning the conductive layer using the oxide layer pattern as an etching mask; forming a first silicon layer on the substrate including the floating gate electrode; forming a tunnel insulation layer on a sidewall of the floating gate electrode and forming a second gate insulation layer on the first gate insulation layer respectively by oxidizing the first silicon layer; forming a control gate electrode on the tunnel insulation layer formed on a sidewall of the floating gate electrode, and on a portion of the second gate insulation layer formed on the substrate adjacent to the floating gate electrode; forming a second silicon layer on the substrate including the control gate electrode; and oxidizing the second silicon layer by thermal oxidation.

In one embodiment, the conductive layer includes polysilicon doped with impurities.

In another embodiment, a thickness ratio of the tunnel insulation layer and the first silicon layer is in a range of about 1.0:0.4 to about 1.0:0.5.

In another embodiment, the tunnel insulation layer is formed by a thermal oxidation process.

In another embodiment, the method further comprises: forming a low concentration impurity diffusion region at a surface portion of the substrate adjacent to the floating gate electrode; and forming high concentration impurity diffusion regions at surface portions of the substrate adjacent to the floating gate electrode and the control gate electrode respectively.

In another embodiment, the method further comprises; forming a gate electrode of a transistor on the second gate insulation layer of a peripheral portion of the substrate. The gate electrode of the transistor and the control gate electrode are simultaneously formed.

According to the present invention, variation in the tip profile variation of the floating gate electrode, which can otherwise occur to the floating gate electrode in a thermal oxidation process for forming the tunnel oxide layer, can be suppressed. Therefore, data erasing characteristics of the non-volatile memory device can be improved. Further, a thickness variation of the gate insulating layer, which may occur in the thermal oxidation process, can be prevented. Thus, data programming characteristics of the non-volatile memory device can be improved.

### BRIEF DESCRIPTION OF THE DRAWINGS

The above and other features and advantages of the present invention will become more apparent by describing in detail example embodiments thereof with reference to the accompanying drawings, in which:

FIGS. 1 to 5 are cross-sectional views illustrating a method of manufacturing a conventional split gate type non-volatile memory device;

FIGS. 6 to 12 are cross-sectional views illustrating a method of manufacturing a split gate type non-volatile memory device in accordance with an example embodiment of the present invention;

FIGS. 13 to 15 are cross-sectional views illustrating a method of manufacturing a split gate type non-volatile memory device in accordance with an example embodiment of the present invention;

FIG. 16 is a cross-sectional view illustrating a method of manufacturing a split gate type non-volatile memory device in accordance with an example embodiment of the present invention;

FIGS. 17 to 19 are cross-sectional views illustrating a method of manufacturing a split gate type non-volatile memory device in accordance with an example embodiment of the present invention; and

FIGS. 20 to 22 are cross-sectional views illustrating a method of manufacturing a split gate type non-volatile memory device in accordance with an example embodiment of the present invention.

### DETAILED DESCRIPTION OF EMBODIMENTS OF THE INVENTION

The invention is described more fully hereinafter with reference to the accompanying drawings, in which example embodiments of the invention are shown. The present invention may, however, be embodied in many different forms and should not be construed as limited to the example embodiments set forth herein. Rather, these example embodiments are provided so that this disclosure will be thorough and complete. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

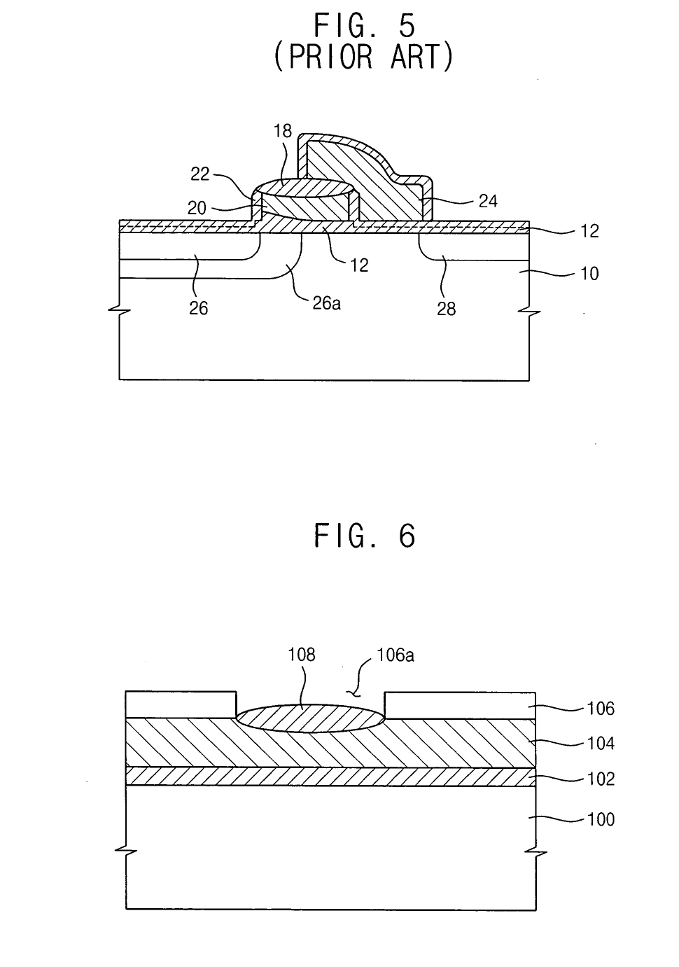

FIGS. 6 to 12 are cross-sectional views illustrating a method of manufacturing a split gate type non-volatile memory device in accordance with an example embodiment of the present invention.

Referring to FIG. 6, a first gate oxide layer 102 is formed on a semiconductor substrate 100 such as a silicon wafer. The first gate oxide layer 102 may be formed by a thermal oxidation process. The first gate oxide layer 102 may serve as a gate insulation layer or a coupling insulation layer.

A first conductive layer 104 is formed on the first gate oxide layer 102. The first conductive layer 104 may be formed using a polysilicon doped with impurities. The first conductive layer 104 may be formed by a lower pressure chemical vapor deposition (LPCVD) process using a silane based gas such as a monosilane gas, a disilane gas, dichlorosilane gas, etc. In one example embodiment of the present invention, the first conductive layer 104 may be formed using a first source gas including the monosilane gas, the disilane gas, the dichlorosilane gas, etc and a second source gas including PH₃ gas. The first conductive layer 104 may be formed at a temperature of about 580° C. to about 620° C. In another example embodiment of the present invention, a polysilicon layer may be initially formed using the silane gas and then impurities may be doped into the polysilicon layer by an impurity diffusion process or an ion implantation process to form the first conductive layer 104 on the first gate oxide layer 102.

A mask pattern 106 is formed on the first conductive layer 104. The mask pattern 106 includes an opening 106a through which a portion of the first conductive layer 104 is exposed. The mask pattern 106 may include a nitride such as silicon nitride, etc. The mask pattern 106 may be formed by an LPCVD process.

The exposed portion of the first conductive layer 104 is oxidized to form an oxide layer pattern 108 on the conductive layer 104. Edge portions of the gate oxide layer have features in the shapes of bird's beak features.

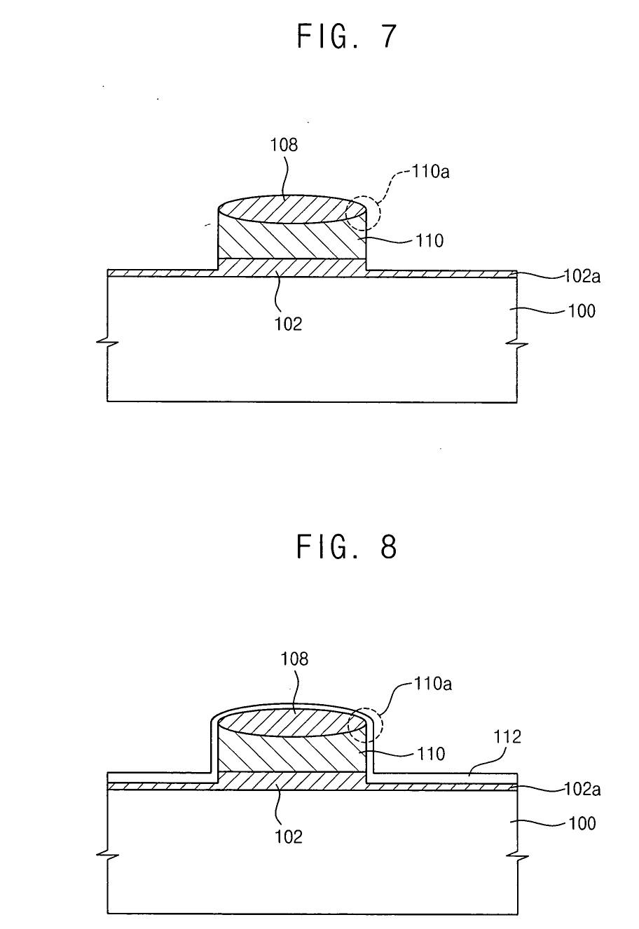

Referring to FIG. 7, the mask pattern 106 is removed from the first conductive layer 104 using an etchant including phosphoric acid, and the first conductive layer 104 is anisotropically and partially etched off using the oxide layer pattern 108 as an etching mask to form a floating gate electrode 110 on the first gate oxide layer 102. In one example embodiment of the present invention, the first gate oxide layer 102 is partially removed by an anisotropic etching process for forming the floating gate electrode 110 to form residual portions 102a of the first gate oxide layer 102 at both sides of the floating gate electrode 110. In another example embodiment of the present invention, the first gate oxide layer 104 is completely removed except for a portion of the first gate oxide layer 102 positioned beneath the floating gate electrode 110 to partially expose the substrate 100.

The floating gate electrode 110 includes upper tip portions 110a that have shapes that corresponding to the shapes of the edge portions of the oxide layer pattern 108.

Referring to FIG. 8, a silicon layer 112 is continuously formed on the oxide layer pattern 108 and the residual portion 102a of the gate oxide layer 102. The silicon layer 112 may include single crystalline silicon, polycrystalline silicon, amorphous silicon, and the like. The silicon layer 112 may be formed, for example, by a chemical vapor deposition (CVD) process using a silane gas or an epitaxial growth process.

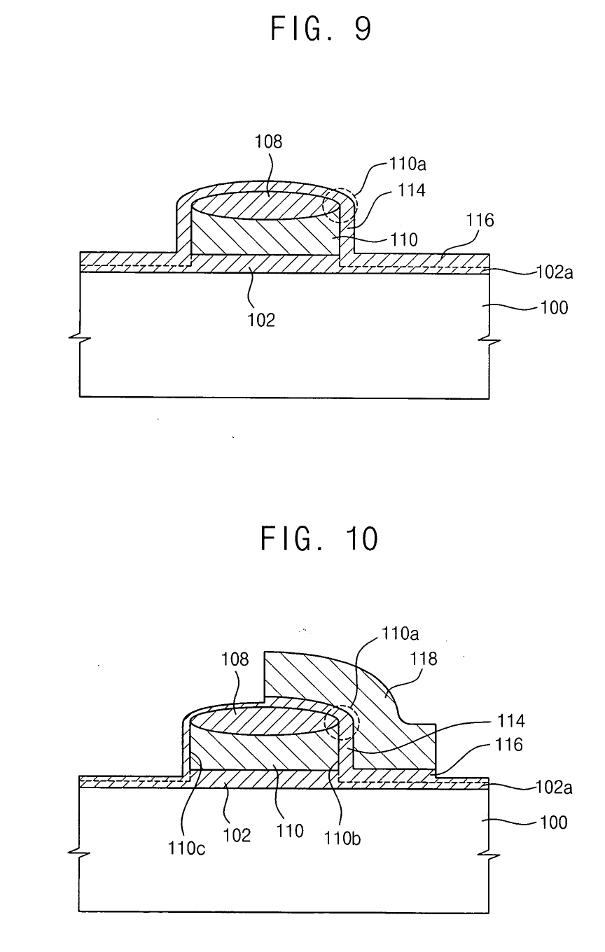

The thickness of the silicon layer can be selected so that the resulting thickness ratio between a subsequently formed tunnel oxide layer 114 (see FIG. 9) and the silicon layer 112 may be in a range of about 1.0:0.4 to about 1.0:0.5, which can operate to suppress the floating gate electrode 110 from becoming varied in its tip profile during the oxidation process for forming the tunnel oxide layer 114.

Referring to FIG. 9, the silicon layer 112 is oxidized to form the tunnel oxide layer 114 on a first sidewall of the floating gate electrode 110 and on the oxide layer pattern 108. Accordingly, with the presence of the silicon layer 112 during the thermal oxidation process, consumption of silicon of the floating gate electrode 110 can be prevented during the thermal oxidation process for forming the tunnel oxide layer 114. Thus, the original tip profile of the floating gate electrode 110 can be retained.

Further, a second gate oxide layer 116 is formed on the residual portions 102a of the first gate oxide layer 102 in a process of forming the tunnel oxide layer 114 and, in this manner, damage to the substrate 100, that could otherwise occur in the anisotropic etching process for forming the floating gate electrode 110, can be avoided.

Referring to FIG. 10, a second conductive layer (not shown) is formed on the tunnel oxide layer 114 and the second gate oxide layer 116. The second conductive layer may be formed, for example, using polysilicon doped with impurities. The second conductive layer may be formed by a process substantially identical to the process for forming the first conductive layer 104.

After a photoresist pattern (not shown) is formed on the second conductive layer, the second conductive layer may be anisotropically and partially etched using the photoresist pattern as an etching mask to form a control gate electrode 118. The control gate electrode 118 is formed on the tunnel oxide layer 114 and on the second gate oxide layer 116 adjacent to the first sidewall 110b.

In an anisotropic etching process for forming the control gate electrode 118, a second sidewall 110c of the floating gate electrode 110 and a portion of the second gate oxide layer 116 adjacent to the second sidewall 110c may become damaged.

Referring to FIG. 11, a re-oxidation process is carried out for curing damage to the second sidewall 110c and the portion of the second gate oxide layer 116. In the re-oxidation process, the spacer layer 120 including silicon oxide is formed on the control gate electrode 118, and a portion of the second sidewall 110c is partially oxidized. In addition, a portion of the first gate oxide layer 102 adjacent to the second sidewall 110c of the floating gate electrode 110 may have an increased thickness.

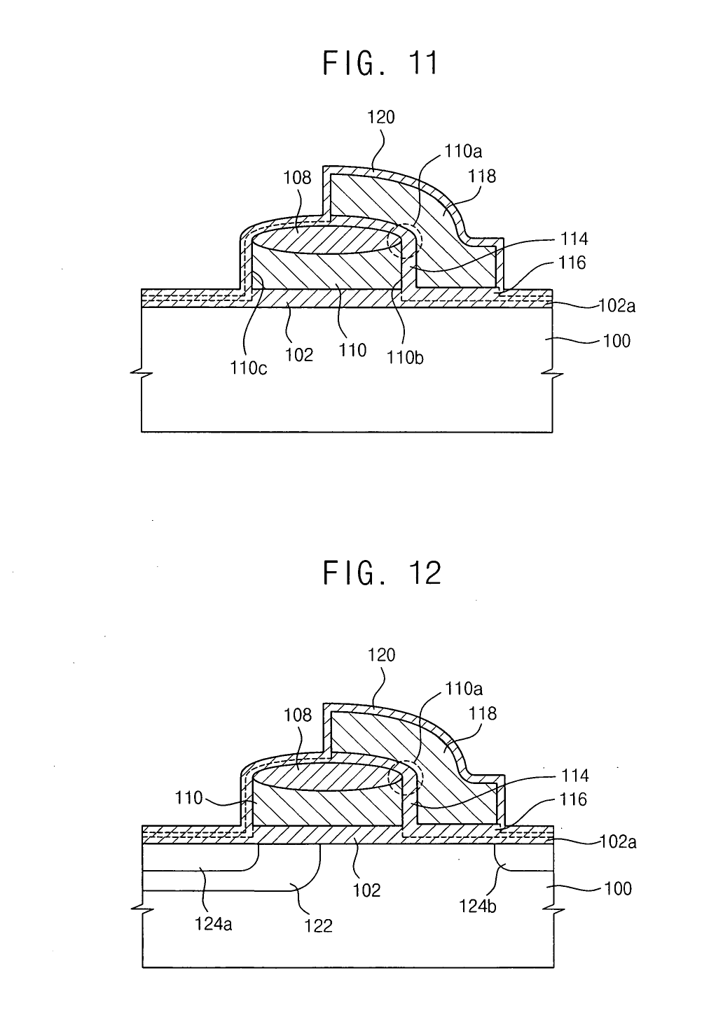

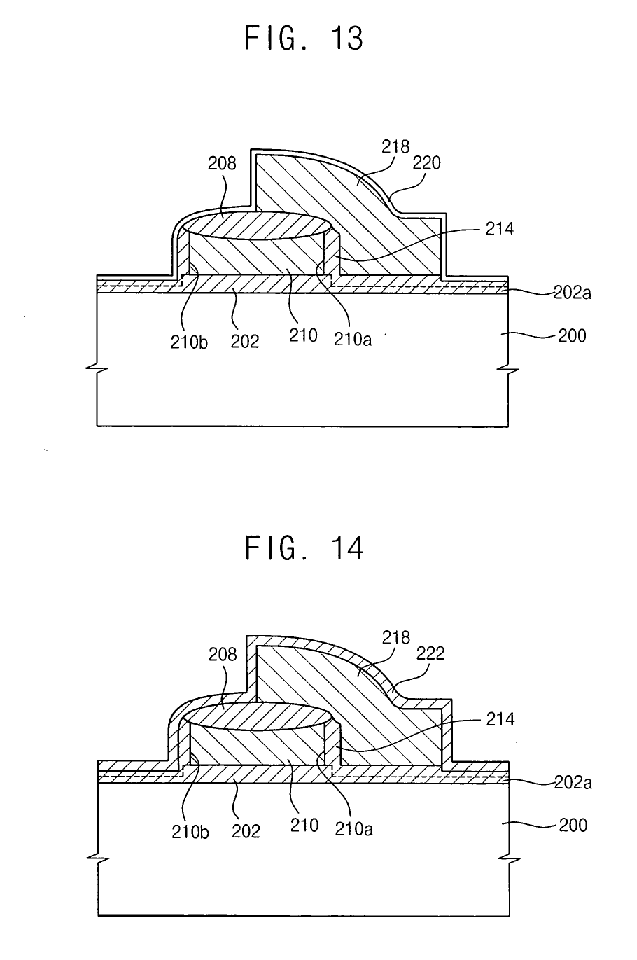

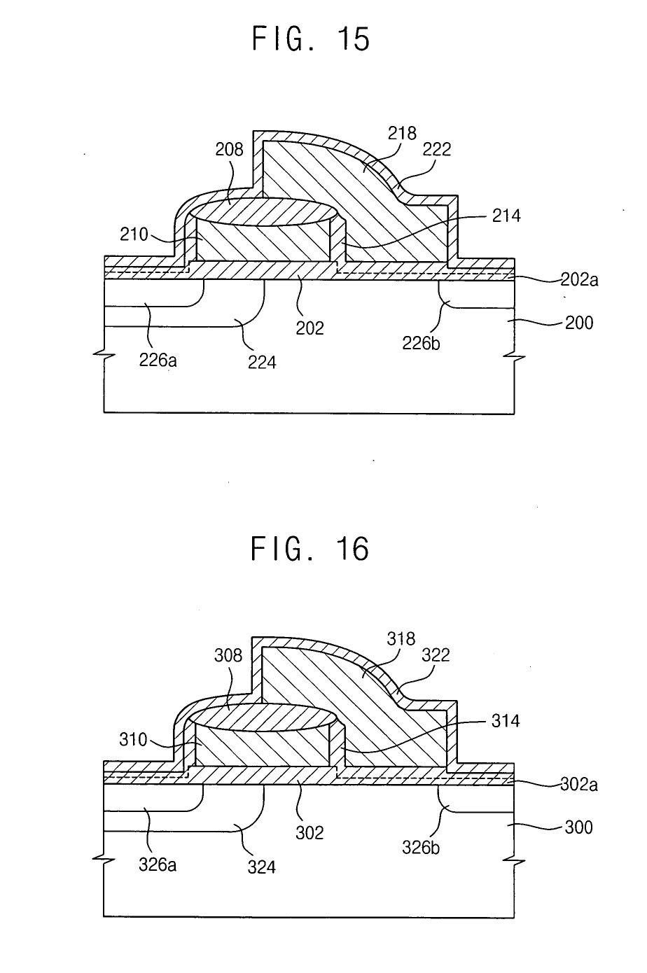

Referring to FIG. 12, a low concentration impurity diffusion region 122 is formed at a surface of the substrate 100 adjacent to the floating gate electrode 110. The low concentration impurity diffusion region 122 may be formed by an ion implantation process and a thermal treatment. The ion implantation process may be selectively performed on the portion of the substrate 100 adjacent to the floating gate electrode 110 using a photoresist pattern as a mask. The thermal treatment may cause impurities to diffuse into a portion of the substrate 100 below the floating gate electrode 110 to widen the low concentration impurity diffusion region 122.

High concentration impurity regions 124a and 124b are formed in portions of the substrate 100 adjacent to the floating gate electrode 110 and the control gate electrode 118, respectively. The high concentration impurity regions 124a and 124b serve as a source region and a drain region. Thus, the manufacture of a split gate type flash memory device is completed.

According to an example embodiment of the present invention, a silicon layer is thermally oxidized to form a tunnel insulation layer. Thus, the tip profile of the floating gate electrode can be prevented from varying and data erasing characteristics can be improved at an upper tip portion between a floating gate electrode 110 and a control gate electrode 118.

FIGS. 13 to 15 are cross-sectional views illustrating a method of manufacturing a split gate type non-volatile memory device in accordance with an example embodiment of the present invention.

Referring to FIG. 13, a gate oxide layer 202 serving as a gate insulating layer is formed on a substrate 200 such as a silicon wafer. An oxide layer pattern 208 and a floating gate electrode 210 are formed on the gate oxide layer 202. In detail, a first conductive layer (not shown) is formed on the gate oxide layer 202 and then a mask pattern (not shown) including an opening is formed on the first conductive layer. The opening may expose a portion of the first conductive layer. The exposed portion of the first conductive layer is partially oxidized to form the oxide layer pattern 208 on the first conductive layer.

The mask pattern is removed from the first conductive layer, and then the first conductive layer is partially and anisotropically etched using the oxide layer pattern 208 as an etching mask to form the floating gate electrode 210 on the gate oxide layer 202.

A sidewall of the floating gate electrode 210 is thermally oxidized to form a tunnel oxide layer 214 on the sidewall of the floating gate electrode 210.

Then, a second conductive layer (not shown) is formed on the substrate 100 including the tunnel oxide layer 214 and the second conductive layer is then patterned to form a control gate electrode 218 on the tunnel oxide layer 214. The control gate electrode 218 is positioned on a portion of the tunnel oxide layer 214 formed on a first sidewall 210a of the floating gate electrode 210, a portion of the gate oxide layer 202 adjacent to the first sidewall 210a and a portion of the oxide layer pattern 208.

In an anisotropic etching process for forming the control gate electrode 218, a portion of the tunnel oxide layer 214 formed on a second sidewall 210b of the floating gate electrode 210 and a portion of the gate oxide layer 202 adjacent to the second sidewall 210b may become damaged. That is, the portion of the tunnel oxide layer 214 formed on a second sidewall 210b of the floating gate electrode 210 and the portion of the gate oxide layer 202 adjacent to the second sidewall 210b may become artially etched. As a result, the thickness of the portion of the tunnel oxide layer 214 formed on the second sidewall 210b of the floating gate electrode 210 may be reduced.

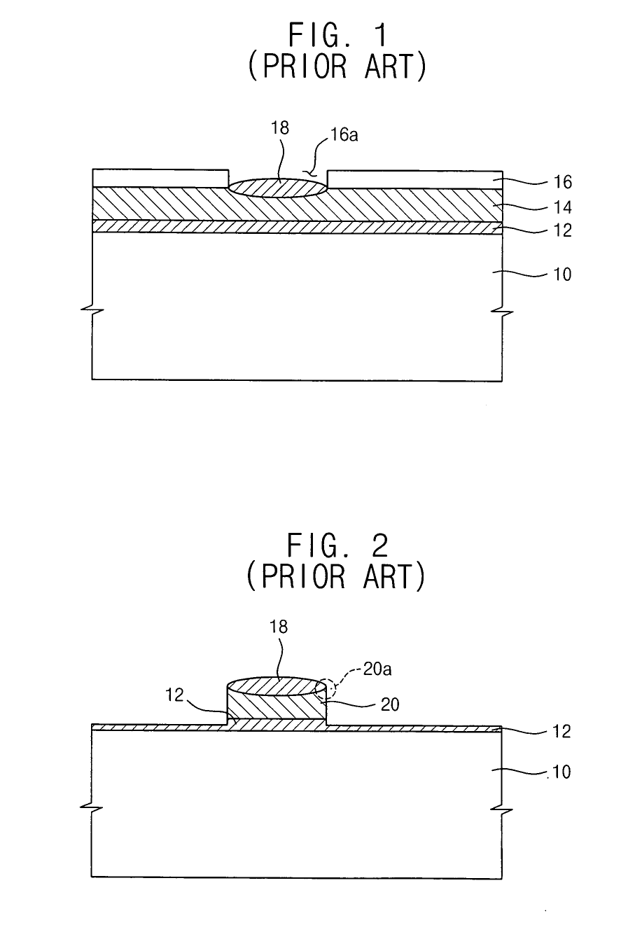

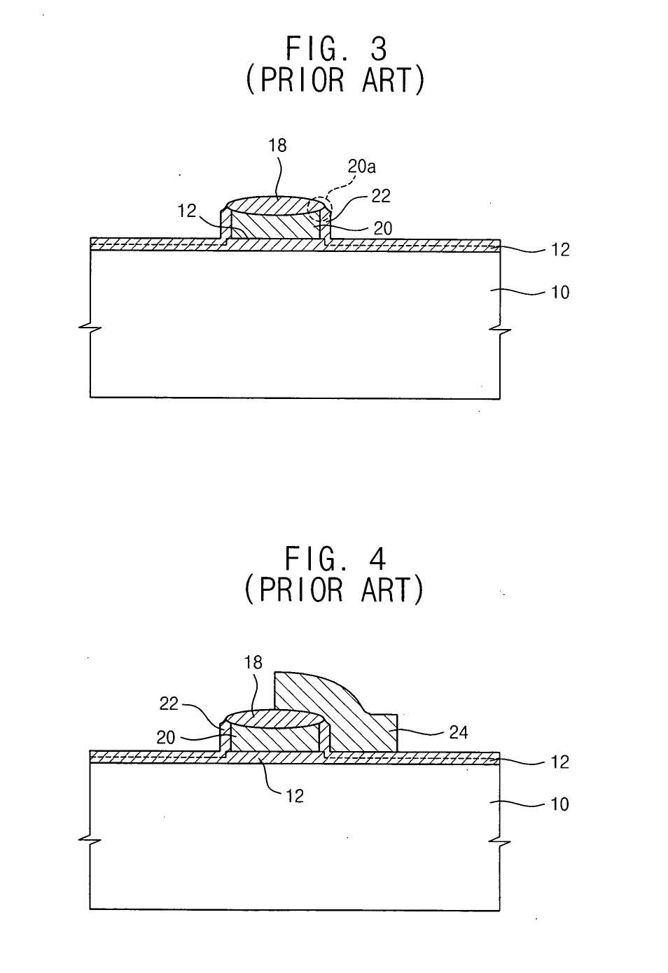

In this example embodiment, the steps of forming the gate oxide layer 202, forming the oxide layer pattern 208, forming the floating gate electrode 210, forming the tunnel oxide layer 214 and forming the control gate electrode 218 may be substantially identical to the processing steps described above with reference to FIGS. 1 to 4.

In the present embodiment, after the control gate electrode 218 is formed, a silicon layer 220 is formed on the substrate 100 including the control gate electrode 218. The silicon layer 220 may be formed, for example, using single crystalline silicon, polycrystalline silicon or amorphous silicon. The silicon layer 220 may be formed by a CVD process or an epitaxial growth process using a silane gas.

Referring to FIG. 14, the silicon layer 220 is thermally oxidized to form a thermal oxidation layer 222 on an entire surface of the substrate including the control gate electrode 218. A portion of the thermal oxidation layer 222 formed on the control gate electrode 218 serves as a spacer layer for the control gate electrode 218.

In a process for forming the thermal oxidation layer 222, any damages, which could have been generated during the anisotropic etching process for forming the control gate electrode 218, can be cured. In particular, the portion of the gate oxide layer 202 adjacent to the second sidewall 210b of the floating gate electrode 210 can be made to have a uniform thickness without increasing the thickness of that portion.

Referring to FIG. 15, a low concentration impurity diffusion region 224 is formed at a surface portion of the substrate 200 adjacent to the floating gate electrode 210. The low concentration impurity diffusion region 224 may be formed by an ion implantation process and a thermal treatment. The ion implantation process may be selectively performed on the portion of the substrate 200 adjacent to the floating gate electrode 210 using a photoresist pattern as a mask. The thermal treatment may cause impurities to diffuse into a portion of the substrate 200 under the floating gate electrode 210 to widen the low concentration impurity diffusion region 224.

High concentration impurity regions 226a and 226b are formed at surface portions of the substrate 200 adjacent to the floating gate electrode 210 and the control gate electrode 218. The high concentration impurity regions 226a and 226b serve as a source region and a drain region. Thus, the manufacture of a split gate type flash memory device is completed.

According to an example embodiment of the present invention, the gate oxide layer 202 interposed between the floating gate electrode 210 and the substrate 200 can maintain a uniform thickness. Thus, the capacitance of the gate oxide layer 202 between the source/drain regions 226a and 226b may be increased to improve programming characteristics of the flash memory device.

FIG. 16 is a cross-sectional view illustrating a method of manufacturing a split gate type non-volatile memory device in accordance with an example embodiment of the present invention.

Referring to FIG. 16, a gate oxide layer 302, an oxide layer pattern 308, a floating gate electrode 310, a tunnel oxide layer 314 and a control gate electrode 318 are formed on a substrate 300 such as a silicon wafer. Steps of forming the gate oxide layer 302, forming the oxide layer pattern 308, forming the floating gate electrode 310, forming the tunnel oxide layer 314 and forming the control gate electrode 318 are substantially identical to the processing steps described with reference to FIG. 14 above. Thus, any further description of these steps will be omitted, in order to avoid redundancy.

After the control gate electrode 318 is formed, a high temperature oxide (HTO) layer 322 is formed on an entire resultant surface of the substrate 300 including the control gate electrode 318. The HTO layer 322 may serve as a spacer layer for the control gate electrode 318. In detail, the HTO layer 322 may be formed using a silane gas at a temperature of about 700° C. to about 900° C. Damage, which can occur during an anisotropic etching process for forming the control gate electrode 318, can be sufficiently cured by the process for forming the HTO layer 322.

After the HTO layer 322 is formed, impurity diffusion regions 324, 326a and 326b are formed in portions of the substrate 300 adjacent to the floating gate electrode 310 and the control gate electrode 318. The low concentration impurity diffusion region 324 and the high concentration impurity diffusion region 326a, which may serve as source regions, are formed at surface portions of the substrate 300 adjacent to the floating gate electrode 310. The high concentration impurity region 326b, which may serve as a drain region, is formed at surface portions of the substrate 300 adjacent to the floating gate electrode 310.

According to an example embodiment of the present invention, consumption of the silicon material of the floating gate electrode 310 and thickness variation of the gate oxide layer 302 can be significantly suppressed. Therefore, the capacitance of the gate oxide layer 302 interposed between the source region 324 and 326a and the floating gate electrode 310 may increase to improve programming characteristics of the flash memory device.

FIGS. 17 to 19 are cross-sectional views illustrating a method of manufacturing a split gate type non-volatile memory device in accordance with an example embodiment of the present invention.

Referring to FIG. 17, a first gate oxide layer 402 and a first conductive layer (not shown) are subsequently formed on a substrate 400 such as a silicon wafer. The first gate oxide layer 402 may function as a gate insulating layer or a coupling insulating layer. The first gate oxide layer 402 may be formed by a thermal oxidation process. The first conductive layer including doped polysilicon may be formed by an LPCVD process and an impurity doping process.

A mask pattern (not shown) including an opening is formed on the first conductive layer. The opening exposes a portion of the first conductive layer. The exposed potion of the first conductive layer is thermally oxidized to form an oxide layer pattern 408 on the first conductive layer.

After the mask pattern is removed, the first conductive layer may be anisotropically etched using the oxide layer pattern as an etching mask to form a floating gate electrode 410 on the first gate oxide layer 402.

A first silicon layer (not shown) is formed on an entire surface of the substrate 400. The first silicon layer is thermally oxidized to form a tunnel oxide layer 414 on sidewalls of the floating gate electrode 410 and to form a second gate oxide layer 416 on a portion of the substrate 400 adjacent to the floating gate electrode 410. A thickness ratio between the tunnel oxide layer 414 and the first silicon layer is in a range of about 1.0:0.4 to about 1.0:0.5.

A second conductive layer (not shown) is formed on an entire surface of the substrate 400. The second conductive layer may be formed using a doped polysilicon. A method of forming the second conductive layer may be substantially identical to that of forming the first conductive layer.

The second conductive layer is patterned to form a control gate electrode 418 on the tunnel oxide layer 414 and the second gate oxide layer 416. The control gate electrode 418 is positioned on a portion of the tunnel oxide layer 414 formed on a first sidewall 410a and the oxide layer pattern 408 and a portion of the second gate oxide layer 416 adjacent to the first sidewall 410a.

Steps of forming the first gate oxide layer 402, forming the oxide layer pattern 408, forming the floating gate electrode 410, forming the tunnel oxide layer 414 and forming the control gate electrode 418 may be substantially identical to the processing steps described above with reference to FIGS. 6 to 10. Any further description of the steps will be omitted in order to avoid redundancy.

After the control gate electrode 418 is formed, a second silicon layer 420 is formed on an entire surface of the substrate 400. The second silicon layer 420 may be formed using single crystalline silicon, polycrystalline silicon, amorphous silicon, etc. The second silicon layer 420 may be formed by a CVD process or an epitaxial growth process using a silane gas.

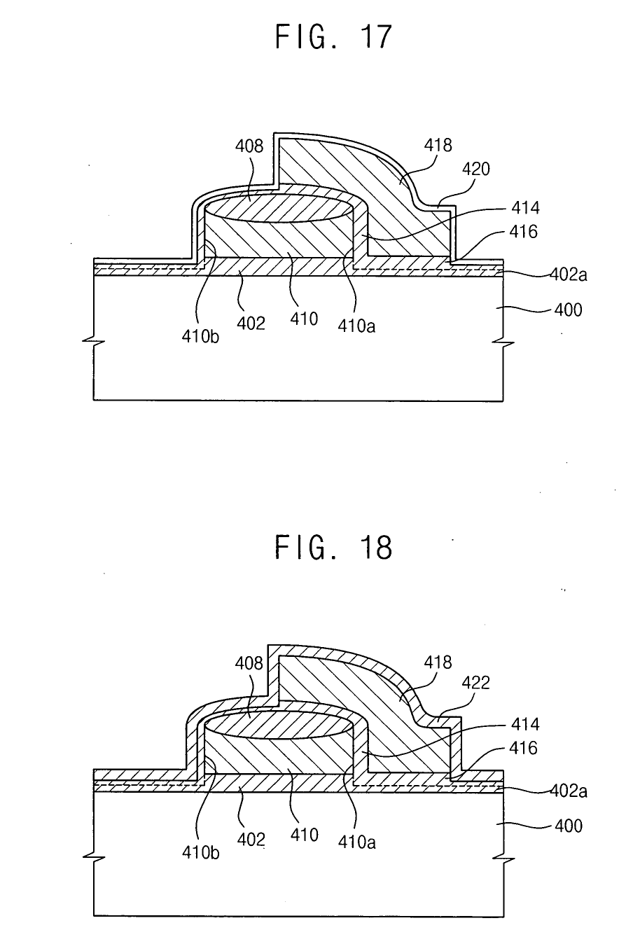

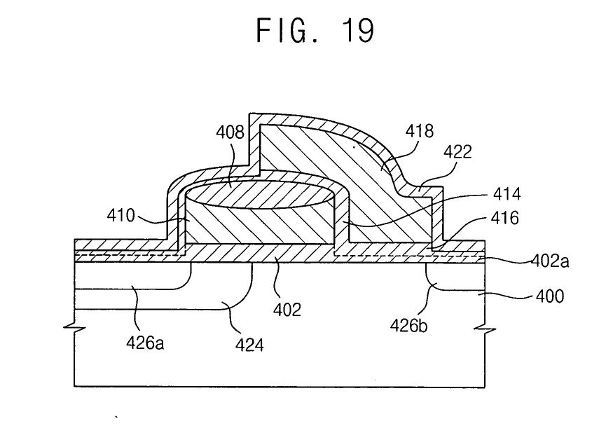

Referring to FIG. 18, the second silicon layer 420 is thermally oxidized to form a thermal oxidation layer 422 on an entire surface of the substrate 400. Thus, damage, which can occur in an anisotropic etching process for forming the control gate electrode 418 can be properly cured. In particular, a portion of the first gate oxide layer 402 adjacent to the second sidewall 410b of the floating gate electrode 410 can be made to have a uniform thickness without increasing the thickness of that portion.

Referring to FIG. 19, a low concentration impurity diffusion region 424 is formed at a surface portion of the substrate 400 adjacent to the floating gate electrode 410. The low concentration impurity diffusion region 424 may be formed, for example, by an ion implantation process and a thermal treatment. The ion implantation process may be selectively performed onto the substrate 400 adjacent to the floating gate electrode 410 using a photoresist pattern as a mask. The thermal treatment may cause impurities to diffuse into a portion of the substrate 400 under the floating gate electrode 410 to widen the low concentration impurity diffusion region 424.

High concentration impurity regions 426a and 426b are formed at surface portions of the substrate 400 adjacent to the floating gate electrode 410 and the control gate electrode 418. The high concentration impurity regions 426a and 426b serve as a source region and a drain region. Thus, a split gate type flash memory device is completed.

According to an example embodiment of the present invention, variation of the tip profile of the floating gate electrode 410 can be prevented and data erasing characteristics can be improved at the upper tip portion of the floating gate electrode between the floating gate electrode 410 and the control gate electrode 418. Further, the gate oxide layer 402 interposed between the floating gate electrode 410 and the substrate 400 can be maintain to have a uniform thickness. Thus, the capacitance of the gate oxide layer 402 between the source/drain regions 426a and 426b may be increased to improve programming characteristics of the flash memory device.

In one example embodiment of the present invention, the second silicon layer 420 is formed and then the second silicon layer is thermally oxidized to form the thermal oxidation layer 422. In another example embodiment of the present invention, an HTO layer may be formed on the substrate 400 including the control gate electrode 418 to improve programming characteristics of the flash memory device.

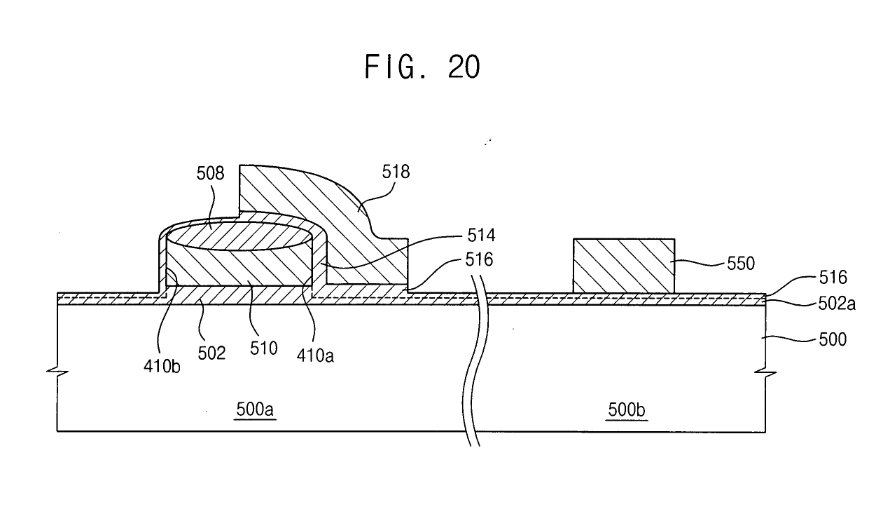

FIGS. 20 to 22 are cross-sectional views illustrating a method of manufacturing a split gate type non-volatile memory device in accordance with an example embodiment of the present invention.

Referring to FIG. 20, an isolation layer (not shown) is formed on a substrate such as a silicon wafer. The isolation layer defines a cell region 500a and a peripheral region 500b. The isolation layer may be formed, for example, by a shallow trench isolation (STI) process.

A first gate oxide layer 502, an oxide layer pattern 508 and a floating gate electrode 510 are formed on the cell region 500a of the substrate 500. In detail, the first gate oxide layer 502, a first conductive layer (not shown) and a mask pattern (not shown) exposing a portion of the first conductive layer are sequentially formed. The exposed portion of the first conductive layer is oxidized to form the oxide layer pattern 508 on the first conductive layer. The first conductive layer is patterned using the oxide layer pattern 508 as an etching mask to form the floating gate electrode 510 on the first gate oxide layer 502.

After the floating gate electrode 510 is formed, a first silicon layer (not shown) is formed on an entire surface of the substrate 500. The first silicon layer is oxidized to form a tunnel oxide layer 514 on a sidewall of the floating gate electrode 500 and a second gate oxide layer 516 on the substrate 500.

As shown in FIG. 20, the first gate oxide layer 502 and the second gate oxide layer 516 are formed on the peripheral region 500b of the substrate 500. Alternatively, a portion of the first gate oxide layer 502 and a portion of the second gate oxide layer 516, which are positioned on the peripheral region 500b, may be selectively removed and a third gate oxide layer may be then formed on the peripheral portion 500b as a gate insulating layer.

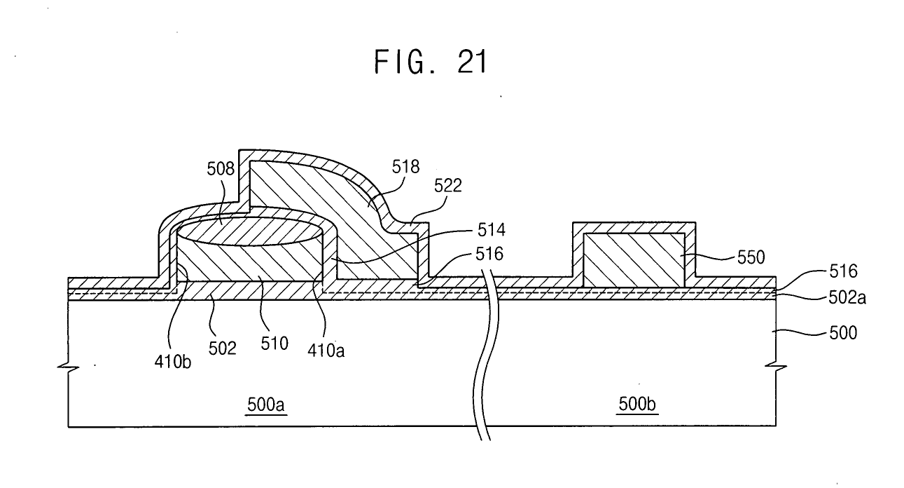

Referring to FIG. 21, a second silicon layer (not shown) is formed on an entire surface of the substrate 500 and the second silicon layer is thermally oxidized to form a thermal oxidation layer 522 on the entire surface of the substrate 500. The thermal oxidation layer 522 can serve as a spacer layer for the control gate electrode 518 in the cell region and for the gate electrode 550 of a transistor in the peripheral region.

In the present example embodiment, damage which can occur during an etching process for forming the control gate electrode 518 and the gate electrode 550 of the transistor, may be cured in the thermal oxidation process for forming the thermal oxidation layer 522. Any thickness variation in a portion of the first gate oxide layer 505 positioned under the floating gate electrode 510 may be suppressed. Further, thickness variation in a portion of the first gate oxide layer 502 and a portion of the second gate oxide layer 516 (or the third gate oxide layer), which are positioned under the gate electrode 550 of the transistor, may be suppressed.

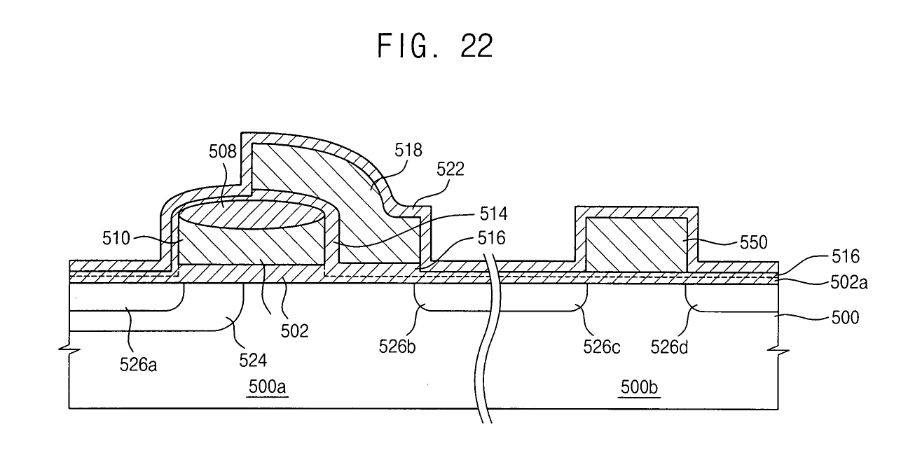

Referring to FIG. 22, a low concentration impurity diffusion region 524 is formed in a portion of the substrate 500 adjacent to the floating gate electrode 510. Impurity regions 526a, 526b, 526c and 526d are formed on portions of the substrate 500 adjacent to the floating gate electrode 510, the control gate electrode 518 and the gate electrode of the transistor, respectively. Thus, a split gate type flash memory device is completed on the cell region 500a and the transistor is completed on the peripheral region 500b.

In an example embodiment of the present invention, erasing and programming characteristics of the flash memory device may be improved and operating characteristics of the transistor formed on the peripheral region may be enhanced.

According to the present invention, variation of the tip profile of a floating gate electrode in a split gate type flash memory device and variation in the thickness of a gate insulating layer may be suppressed or prevented. Thus, programming and erasing characteristics of the split gate type flash memory device and the operating characteristics of a transistor may be improved.

While the invention has been particularly shown and described with references to preferred embodiments thereof, it will be understood by those skilled in the art that various changes in form and details may be made herein without departing from the spirit and scope of the invention as defined by the appended claims.

What is claimed is:

1. A method of manufacturing a non-volatile memory device, comprising:
forming a first gate insulation layer and a conductive layer on a substrate;
forming an oxide layer pattern by partially oxidizing a top portion of the conductive layer;
forming a floating gate electrode on the first gate insulation layer by patterning the conductive layer using the oxide layer pattern as an etching mask;
forming a silicon layer on the substrate including the floating gate electrode;
forming a tunnel insulation layer on a sidewall of the floating gate electrode and forming a second gate insulation layer on the first gate insulation layer by oxidizing the silicon layer; and
forming a control gate electrode on the tunnel insulation layer and the second gate insulation layer.

2. The method of claim 1, wherein forming the oxide layer pattern comprises:
forming a mask pattern on the conductive layer, the mask pattern including an opening through which a portion of the conductive layer is exposed; and
oxidizing the exposed portion of the conductive layer pattern to form the oxide layer pattern.

3. The method of claim 1, wherein the conductive layer includes polysilicon doped with impurities.

4. The method of claim 1, wherein the silicon layer includes one selected from the group consisting of a single crystalline silicon layer, a poly crystalline silicon layer, and an amorphous silicon layer.

5. The method of claim 1, wherein a thickness ratio between the tunnel insulation layer and the silicon layer is in a range of about 1.0:0.4 to about 1.0:0.5.

6. The method of claim 1, wherein the tunnel insulation layer is formed by a thermal oxidation process.

7. The method of claim 1, wherein forming the control gate electrode comprises:
forming a second conductive layer on the substrate including the tunnel insulation layer and the second gate insulation layer; and
patterning the second conductive layer to form the control gate electrode, the control gate electrode being positioned both on the tunnel insulation layer formed on the sidewall of the floating gate electrode and on a portion of the second gate insulation layer adjacent to the floating gate electrode.

8. The method of claim 1, further comprising:
forming a low concentration impurity diffusion region at a surface portion of the substrate adjacent to the floating gate electrode; and
forming high concentration impurity diffusion regions at surface portions of the substrate adjacent to the floating gate electrode and the control gate electrode respectively.

9. A method of manufacturing a non-volatile memory device, comprising:
forming a gate insulation layer and a conductive layer on a substrate;
forming an oxide layer pattern by partially oxidizing a top portion of the conductive layer;
forming a floating gate electrode on the first gate insulation layer by patterning the conductive layer using the oxide layer pattern as an etching mask;
forming a tunnel insulation layer by oxidizing a surface of the floating gate electrode;
forming a control gate electrode on the tunnel insulation layer formed on a sidewall of the floating gate electrode, and on a portion of the gate insulation layer formed on the substrate adjacent to the floating gate electrode;
forming a silicon layer on the substrate including the control gate electrode; and
oxidizing the silicon layer by thermal oxidation.

10. The method of claim 9, wherein the control gate electrode includes a polysilicon doped with impurities.

11. A method of manufacturing a non-volatile memory device, comprising:
forming a gate insulation layer and a conductive layer on a substrate;
forming an oxide layer pattern by partially oxidizing a top portion of the conductive layer;
forming a floating gate electrode on the first gate insulation layer by patterning the conductive layer using the oxide layer pattern as an etching mask;
forming a tunnel insulation layer by oxidizing a surface of the floating gate electrode;
forming a control gate electrode on the tunnel insulation layer formed on a sidewall of the floating gate electrode, and on a portion of the gate insulation layer formed on the substrate adjacent to the floating gate electrode; and
forming a high temperature oxidation layer on the substrate including the control gate electrode.

12. The method of claim 11, wherein the high temperature oxidation layer is formed by a chemical vapor deposition process at a temperature of about 700° C. to about 900° C.

13. A method of manufacturing a non-volatile memory device, comprising:
forming a first gate insulation layer and a conductive layer on a substrate;
forming an oxide layer pattern by partially oxidizing a top portion of the conductive layer;
forming a floating gate electrode on the first gate insulation layer by patterning the conductive layer using the oxide layer pattern as an etching mask;
forming a first silicon layer on the substrate including the floating gate electrode;
forming a tunnel insulation layer on a sidewall of the floating gate electrode and forming a second gate insulation layer on the first gate insulation layer by oxidizing the first silicon layer;
forming a control gate electrode on the tunnel insulation layer formed on a sidewall of the floating gate electrode, and on a portion of the second gate insulation layer formed on the substrate adjacent to the floating gate electrode;
forming a second silicon layer on the substrate including the control gate electrode; and
oxidizing the second silicon layer by thermal oxidation.

14. The method of claim 13, wherein the conductive layer includes polysilicon doped with impurities.

15. The method of claim 13, wherein a thickness ratio of the tunnel insulation layer and the first silicon layer is in a range of about 1.0:0.4 to about 1.0:0.5.

16. The method of claim 13, wherein the tunnel insulation layer is formed by a thermal oxidation process.

17. The method of claim 13, further comprising:
forming a low concentration impurity diffusion region at a surface portion of the substrate adjacent to the floating gate electrode; and
forming high concentration impurity diffusion regions at surface portions of the substrate adjacent to the floating gate electrode and the control gate electrode respectively.

18. The method of claim 13, further comprising forming a gate electrode of a transistor on the second gate insulation layer of a peripheral portion of the substrate; and
wherein the gate electrode of the transistor and the control gate electrode are simultaneously formed.
